(19) United States
(12) Patent Application Publication
(10) Pub. No.: US 2004/0212066 A1
(43) Pub. Date: Oct. 28, 2004

(54) Multi-chips stacked package

(75) Inventor: Sung-Fei Wang, Kaohsiung (TW)

Correspondence Address: BACON & THOMAS, PLLC, 625 SLATERS LANE, FOURTH FLOOR, ALEXANDRIA, VA, 22314

(73) Assignee: Advanced Semiconductor Engineering, Inc., Kaoshiung (TW)

(21) Appl. No.: 10/747,316

(22) Filed: Dec. 30, 2003

(30) Foreign Application Priority Data
Apr. 23, 2003 (TW) 092109528

(51) Int. Cl. H01L 23/02

(52) U.S. Cl. 257/686

(57) ABSTRACT

A multi-chips stacked package at least comprises a substrate, a lower chip, an upper chip, an adhesive layer, a supporting body and an encapsulation. The lower chip is disposed on the substrate and the upper chip is attached to the lower chip via the adhesive layer. In addition, the lower chip and the upper chip are electrically connected to the substrate via first electrically conductive wires and second electrically conductive wires respectively. Furthermore, the supporting body is disposed on the substrate, surrounds the periphery of the first chip and covered by the second chip. The top of the supporting body is apart from the back surface of the second chip with a distance. Accordingly, when the second electrically conductive wires are bonded the upper chip to the substrate with a larger bonding force to cause the upper chip to be tilted more, the supporting body will support the upper chip and prevent the upper chip from contacting the first electrically conductive wires.

### BACKGROUND OF THE INVENTION

1. Field of Invention

This invention relates to a multi-chips stacked package. More particularly, the present invention is related to a multi-chips stacked package with a supporting body for preventing the upper chip from being tilted to damage electrically conductive wires connecting the lower chip and the substrate.

2. Related Art

Recently, integrated circuit (chip) packaging technology is becoming a limiting factor for the development in packaged integrated circuits of higher performance. Semiconductor package designers are struggling to keep pace with the increase in pin count, size limitations, low profile, and other evolving requirements for packaging and mounting integrated circuits.

Due to the assembly package in miniature and the integrated circuits operation in high frequency, MCM (multi-chips module) packages are commonly used in said assembly packages and electronic devices. Usually, said MCM package mainly comprises at least two chips encapsulated therein, for example a processor unit, a memory unit and related logic units, so as to upgrade the electrical performance of said assembly package. In addition, the electrical paths between the chips in said MCM package are short so as to reduce the signal delay and save the reading and writing time.

Generally speaking, conventional multi-chips module (MCM) packages shall be a multi-chips side-by-side package or a multi-chips stacked package. As shown in FIG. 1, it illustrates a multi-chips stacked package patented in U.S. Pat. No. 5,323,060 to Rich Fogal et al. entitled “Multichip Module Having a Stacked Chip Arrangement” and said stacked package mainly comprises a substrate 110, a lower chip 120 and an upper chip 130. Therein, the upper chip 130 is disposed on the lower chip 120 by wire-bonding and chip-stacking technology, and electrically connected to the substrate 110. Specifically, the U.S. Pat. No. 5,323,060 is characterized in that an adhesive layer 140 is interposed between the lower chip 120 and the upper chip 130 so as to provide a clearance or a gap for wires bonding the lower chip 120 to the substrate 110. Namely, the bonding wires 150 can be accommodated in the clearance. In addition, the thickness of the adhesive layer 140 shall be larger than the distance between the active surface of the upper chip 130 and the loop height of the bonding wires 150 so as to prevent the upper chip 130 from contacting the wires 150. Generally speaking, the adhesive layer 140 is epoxy or tape. However, it is difficult to provide a uniform adhesive layer with an eight (8) mils thickness. It should be noted that when the upper chip 130 is larger than the lower chip 110 in size and the upper chip 130 is electrically connected to the substrate 110 via wires, the upper chip 130 is tilted to cause the wires 150 to be damaged due to larger wire-bonding force and the difficulty in controlling the thickness of the adhesive layer 140. Moreover, it is easy to control the thickness of the adhesive layer 140 by taking tape with an eight (8) mils thickness. However, the manufacturing cost is higher.

Accordingly, another multi-chips stacked package is provided as shown in FIG. 2. Said package is characterized in that an intermediate chip 160 is interposed between the lower chip 110 and the upper chip 130 through two adhesive layers 162 and 164. The adhesive layers 162 and 164 are made of thermosetting epoxy. Although, the intermediate chip 160 can define a clearance to provide the lower chip 162 enough space for the electrically conductive wires 150 bonding the lower chip 162 to the substrate 110. However, when the electrically conductive wires 164 are bonded the upper chip 130 to the substrate 110 by a larger wire-bonding force, not only the adhesive layer 164 between the upper chip 130 and the intermediate chip 160 but also the adhesive layer 162 between the lower chip 110 and the intermediate chip 160 will be more difficult to control. Accordingly, the upper chip 130 will be easily tilted so as to cause the electrically conductive wires 150 connecting the lower chip 120 and the substrate 110 to be damaged.

Therefore, providing another assembly package to solve the mentioned-above disadvantages is the most important task in this invention.

### SUMMARY OF THE INVENTION

In view of the above-mentioned problems, an objective of this invention is to provide a multi-chips stacked package with a supporting body to prevent the upper chip from being tilted to contact electrically conductive wires for connecting the lower chip and the substrate.

To achieve the above-mentioned objective, a multi-chips stacked package is provided, wherein the multi-chips stacked package mainly comprises a substrate, an upper chip, a lower chip, an adhesive layer, a supporting body and an encapsulation. Therein, the lower chip is disposed on the substrate and electrically connected to the substrate via first electrically conductive wires; the upper chip is disposed on the lower chip via the adhesive layer and electrically connected to the substrate via second electrically conductive wires; and the supporting body is disposed on the substrate and compasses the lower chip so as to have the supporting body covered by the upper chip. Therein, the top of the supporting body is apart from the back surface of the upper chip with a distance and is higher than the top of the arc of the first electrically conductive wires. In such a manner, the upper chip can be prevented from contacting the first electrically conductive wires due to the tilt of the upper chip when the second wires are bonded the upper chip to the substrate. Moreover, the upper chip can also be prevented from being tilted more to have the upper chip being without stability and separated from the adhesive layer.

Next, another multi-chips stacked package is provided, wherein the multi-chips stacked package mainly comprises a substrate, an upper chip, a lower chip, an adhesive layer, a supporting body and an encapsulation. Therein, the lower chip is disposed on the substrate; the upper chip is disposed on the lower chip via the adhesive layer and electrically connected to the substrate via electrically conductive wires; the lower chip is electrically connected to the substrate via bumps by flip-chip bonding technology; and the supporting body is disposed on the substrate and compasses the lower chip so as to have the supporting body covered by the upper chip. Therein, the top of the supporting body is apart from the back surface of the upper chip with a distance. In such a manner, the upper chip can be prevented from being tilted more to have the upper chip being without stability and separated from the adhesive layer when the wires are bonded the upper chip to the substrate.

In summary, this invention is related to a multi-chips stacked package with a supporting body formed on the substrate and covered by the upper chip so as to define a distance between the top of the supporting body and the back surface of the upper chip. In such a manner, when the wires are bonded the upper chip to the substrate with a larger bonding force to cause the upper chip to be tilted more, the supporting body will support the upper chip. Accordingly, the upper chip will be in counterpoise so as to have the wire bonder aligned with the bonding pads on the upper chip more precisely.

### BRIEF DESCRIPTION OF THE DRAWINGS

The invention will become more fully understood from the detailed description given herein below illustrations only, and thus are not limitative of the present invention, and wherein:

FIG. 1 is a cross-sectional view of the conventional multi-chips stacked package;

FIG. 2 is a cross-sectional view of another conventional multi-chips stacked package;

FIG. 3 is a cross-sectional view of a multi-chips stacked package according to the first embodiment; and

FIG. 4 is a cross-sectional view of a multi-chips stacked package according to the second embodiment.

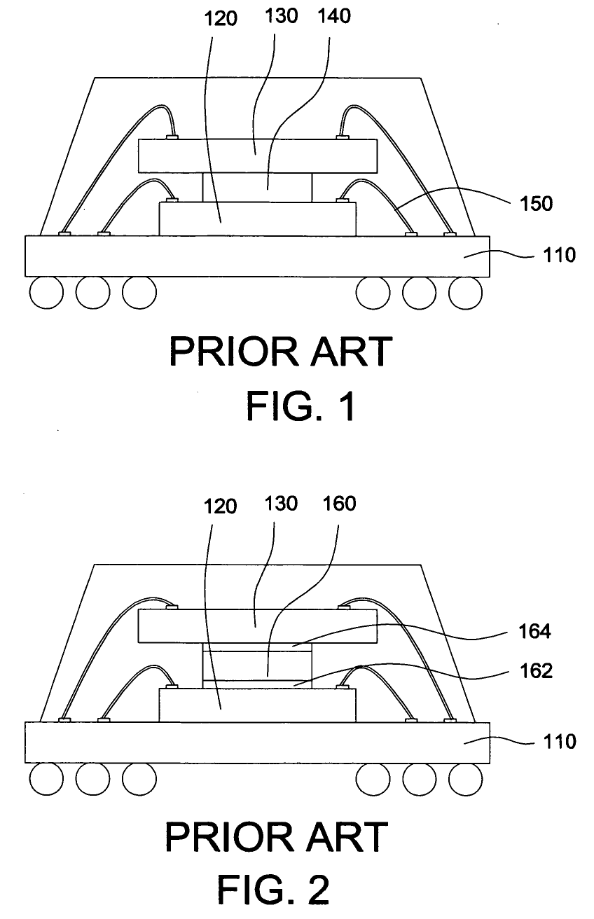

### DETAILED DESCRIPTION OF THE INVENTION

The multi-chips stacked package according to the preferred embodiment of this invention will be described herein below with reference to the accompanying drawings, wherein the same reference numbers refer to the same elements.

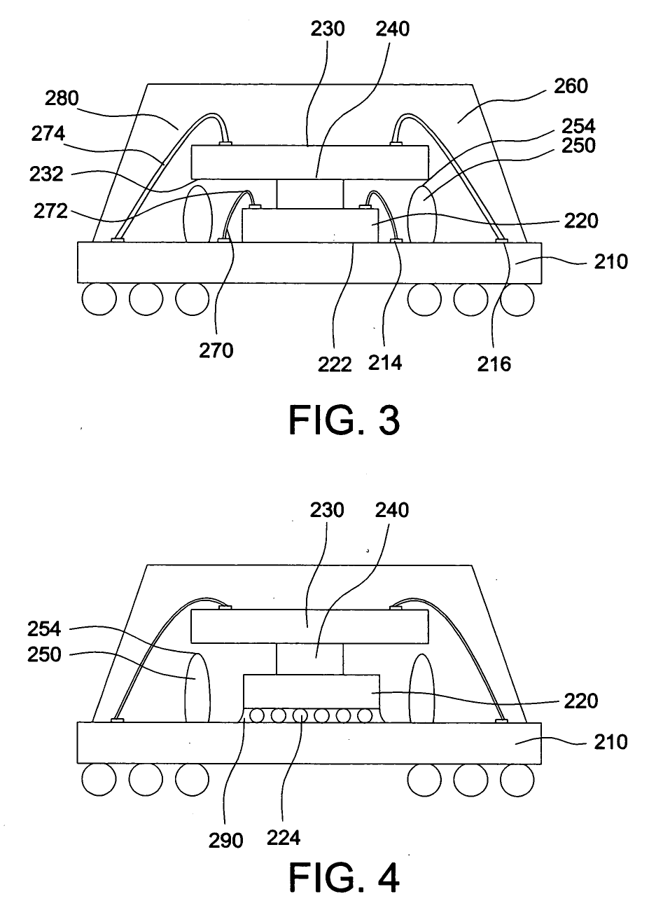

In accordance with a first preferred embodiment as shown in FIG. 3, there is provided a multi-chips stacked package. The multi-chips stacked package mainly comprises a substrate 210, a lower chip 220, an upper chip 230, an adhesive layer 240, a supporting body 250, and an encapsulation 260. The lower chip 220 has a back surface 222 attached on the substrate 210 and electrically connected to the substrate 210 via a plurality of first electrically conductive wires 270. Moreover, an adhesive layer 240 is interposed between the upper chip 230 and the lower chip 220, and the upper chip 230 is electrically connected to the substrate 210 through a plurality of second electrically conductive wires 280. Besides, the supporting body 250 is disposed on the substrate 210 and located between the first wire-bonding pad 214 and the second wire-bonding pad 216 so as to be covered by the upper chip 230, wherein the first wire-bonding pad 214 connects the first electrically conductive wire 272 and the second wire-bonding pad 216 connects the second electrically conductive wire 274. Therein, the top 254 of the supporting body 250 is apart from the back surface 232 of the upper chip 230 with a distance and is higher than the top of the arc of the first electrically conductive wires 272. Accordingly, when the second electrically conductive wires 280 are bonded the upper chip 230 to the substrate 210 with a larger bonding force to cause the upper chip 230 to be tilted more, the supporting body 250 will support the upper chip 230 and prevent the upper chip 230 from contacting the first electrically conductive wires. Moreover, the upper chip 230 can also be prevented from being tilted more and having the upper chip 230 separated from the adhesive layer 240 when the first electrically conductive wires 272 are bonded the upper chip 230 to the substrate 210.

In addition, as shown in FIG. 4, there is provided another multi-chips stacked package in accordance with the second preferred embodiment of this invention. The difference of the second embodiment from the first one is that the lower chip 220 is mounted and electrically connected to the substrate 210 via a plurality of electrically conductive bumps 224 by flip-chip bonding technology. Moreover, an underfill 290 is disposed between the lower chip 220 and the substrate 210 so as to prevent the package from being damaged due to the mismatch of the coefficient of thermal expansion between the substrate 210 and the lower chip 220. Furthermore, an adhesive layer 240 is interposed between the upper chip 230 and the lower chip 220. Accordingly, said supporting body 250 can absorb excessive bonding force generated by the process of bonding the electrically conductive wires to the upper chip 230 so as to prevent the upper chip 230 from being tilted more to cause the electrically conductive wires 280 bonded the bonding pads of the upper chip 230 to the wire-bonding pad 216 inaccurately.

As shown above, the supporting body 250 may be made of epoxy, resin or underfill, for example a dam-like epoxy or dam-like underfill. Therein, the dam-like epoxy or dam-like underfill may be disposed on the substrate 210 by the method of dispensing or screen-printing. Specifically, the supporting body 250 may be a bump between the lower chip 220 and the wire-bonding pad or a bar surrounding the lower chip 220. In addition, the supporting body 250 may be a metal bump, for example a solder bump and a gold bump, located on a dummy pad located on the substrate. Therein, the solder bump may be formed by the method of screen-printing or plating, and the gold bump may be formed by the method of wire-bonding.

Although the invention has been described in considerable detail with reference to certain preferred embodiments, it will be appreciated and understood that various changes and modifications may be made without departing from the spirit and scope of the invention as defined in the appended claims.

What is claimed is:

1. A multi-chips stacked package, comprising:
a substrate having an upper surface;
a lower chip having a first active surface and a first back surface, wherein the lower chip is disposed on the upper surface of the substrate and electrically connected to the substrate via a plurality of first electrically conductive wires;
an adhesive layer disposed on the first active surface of the lower chip;
an upper chip having a second active surface and a second back surface, wherein the upper chip is disposed on the adhesive layer and electrically connected to the substrate via a plurality of second electrically conductive wires; and
a supporting body disposed on the substrate and covered by the upper chip.

2. The multi-chips stacked package of claim 1, wherein the top of the supporting body is higher than the top of the arc of each of the first electrically conductive wires.

3. The multi-chips stacked package of claim 1, wherein the top of the supporting body is lower than the second back surface of the upper chip.

4. The multi-chips stacked package of claim 1, wherein the substrate has a first wire-bonding pad formed on the upper surface, and the first wire-bonding pad is connected to the first electrically conductive wire.

5. The multi-chips stacked package of claim 4, wherein the supporting body is located at the outside of the first wire-bonding pad.

6. The multi-chips stacked package of claim 1, wherein the supporting body surrounds the lower chip.

7. The multi-chips stacked package of claim 1, wherein the supporting body is made of epoxy.

8. The multi-chips stacked package of claim 1, wherein the supporting body is a metal bump.

9. The multi-chips stacked package of claim 8, wherein the metal bump is a solder bump.

10. The multi-chips stacked package of claim 8, wherein the metal bump is a gold bump.

11. The multi-chips stacked package of claim 1, wherein the top of the adhesive layer is higher than the top of the arc of each of the first electrically conductive wires.

12. The multi-chips stacked package of claim 1, further comprising a plurality of solder balls formed on the lower surface of the substrate.

13. The multi-chips stacked package of claim 6, wherein the supporting body surrounds the lower chip in a ring form.

14. The multi-chips stacked package of claim 1, wherein the upper chip is larger than the lower chip in size.

15. A multi-chips stacked package, comprising:
a substrate having an upper surface;
a lower chip having a first active surface and a first back surface, wherein the first active surface of the lower chip is mounted on the upper surface of the substrate and electrically connected to the substrate via a plurality of bumps;
an adhesive layer disposed on the first active surface of the lower chip;
an upper chip having a second active surface and a second back surface, wherein the upper chip is disposed on the adhesive layer and electrically connected to the substrate via a plurality of second electrically conductive wires; and
a supporting body disposed on the substrate and covered by the upper chip.

16. The multi-chips stacked package of claim 15, wherein the upper chip is larger than the lower chip in size.

17. The multi-chips stacked package of claim 15, wherein the top of the supporting body is lower than the second back surface of the upper chip.

18. The multi-chips stacked package of claim 15, wherein the supporting body is located at the outside of the lower chip.

19. The multi-chips stacked package of claim 15, wherein the supporting body surrounds the lower chip.

20. The multi-chips stacked package of claim 15, wherein the supporting body is made of epoxy.

21. The multi-chips stacked package of claim 15, wherein the supporting body is a metal bump.
